(19) United States
(12) Patent Application Publication
(10) Pub. No.: US 2025/0228002 A1
(43) Pub. Date: Jul. 10, 2025

(54) ELECTRONIC DEVICE AND METHOD OF MANUFACTURING THE SAME

(71) Applicant: InnoLux Corporation, Miao-Li County (TW)

(72) Inventor: Ming-Chuan WANG, Miao-Li County (TW)

(21) Appl. No.: 18/973,532

(22) Filed: Dec. 9, 2024

(30) Foreign Application Priority Data
Jan. 5, 2024 (CN) 202410020395.5

(51) Int. Cl. H10D 86/40; H10D 86/01; H10D 86/60

(52) U.S. Cl. CPC H10D 86/443; H10D 86/021; H10D 86/60

(57) ABSTRACT

An electronic device includes a first substrate, a signal line, an insulating layer, a conductor layer, and a connection layer. The signal line is disposed on the first substrate. The insulating layer is disposed on the signal line and includes a first opening and a second opening that expose the signal line. The conductor layer is disposed in the first opening, the second opening, and on the signal line. The connection layer extends from the first opening to the second opening and electrically connects to the signal line through the conductor layer.

### CROSS REFERENCE TO RELATED APPLICATIONS

This Application claims priority of China Patent Application No. 2024100203955, filed on Jan. 5, 2024, the entirety of which is incorporated by reference herein.

### BACKGROUND

### Field of the Invention

The present disclosure relates to electronic devices and methods of manufacturing the same, and in particular, to electronic devices for preventing disconnection and methods of manufacturing the same.

### Description of the Related Art

The signal lines of electronic devices (such as scan lines, data lines, power lines, and signal driving lines, etc.) may experience disconnections due to the presence of particles, substrate warpage, or other processing issues. Therefore, it is necessary to resolve these problems by repairing the signal lines.

### SUMMARY

An embodiment of the present disclosure provides an electronic device. The electronic device includes a first substrate, a signal line, an insulating layer, a conductor layer, and a connection layer. The signal line is disposed on the first substrate. The insulating layer is disposed on the signal line and includes a first opening and a second opening that expose the signal line. The conductor layer is disposed in the first opening, the second opening, and on the signal line. The connection layer extends from the first opening to the second opening and electrically connects the signal line through the conductor layer.

Another embodiment of the present disclosure provides a method of manufacturing an electronic device. The method includes providing a first substrate, forming a signal line on the first substrate, forming an insulating layer on the signal line, and patterning the insulating layer to form a first opening and a second opening. The first opening and the second opening expose the signal line. The method further includes forming a conductor layer in the first opening and the second opening and on the signal line, and forming a connection layer that extends from the first opening to the second opening. The connection layer is electrically connected to the signal line through the conductor layer.

### BRIEF DESCRIPTION OF THE DRAWINGS

Aspects of the present disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion. It is also emphasized that the drawings appended illustrate only typical embodiments of this disclosure and are therefore not to be considered limiting in scope, for the disclosure may apply equally well to other embodiments.

FIGS. 1-6 are cross-sectional views of the intermediate stages of manufacturing an electronic device, in accordance with some embodiments.

FIG. 7 is a top view of the intermediate stages of manufacturing an electronic device, in accordance with some embodiments.

FIGS. 8-9 are cross-sectional views of the intermediate stages of manufacturing an electronic device, in accordance with other embodiments.

### DETAILED DESCRIPTION

The electronic device according to the present disclosure are described in detail in the following description. It should be understood that in the following detailed description, numerous embodiments are set forth in order to implementing different aspects of some embodiments of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions, such as “lower”, “bottom”, “higher,” or “top,” may be used in the embodiments to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer”, may indicate that the first material layer is in direct contact with the second material layer, or it may indicate that the first material layer is in indirect contact with the second material layer. In the situation where the first material layer is in indirect contact with the second material layer, there may be one or more other material layers between the first material layer and the second material layer. However, the expression “the first material layer is directly disposed on the second material layer” means that the first material layer is in direct contact with the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. Accordingly, the first element in the specification may refer to the second element in the claims.

In some embodiments of the present disclosure, regarding the terms such as “connected to”, “coupled to”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected” or “electrically coupled” may include any direct or indirect electrical connection means.

In the following descriptions, terms “about,” “substantially,” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. When there is no specific description, the expression “in a range from the first value to the second value” or “between the first value and the second value” means that the range includes the first value, the second value, and other values in between. In addition, certain errors between any two values or directions for comparison may be acceptable. If a first value is equal to a second value, it indicates that a margin of error of about 10% may exist between the first and second values. If a first direction is perpendicular to a second direction, an angle difference between the first direction and the second direction may be between 80 degrees and 100 degrees; if the first direction is parallel to the second direction, an angle difference between the first direction and the second direction may be between 0 degrees and 10 degrees.

In addition, measurement of thickness, length, width, or measurement of distance or interval between elements may be done by applying an optical microscope (OM), a scanning electron microscope (SEM), an alpha step (α-step) profilometer, an ellipsometer, or any other appropriate measurement method. Specifically, according to some embodiments, the SEM may be applied to obtain a cross-sectional image of a to-be-measured element, and the thickness, length, width of each element or the distance or the interval between the elements may be measured.

Certain terminologies will be used to refer to specific devices throughout the specification and the appended claims of the present disclosure. People skilled in the art should understand that manufacturers of electronic devices may refer to same elements under different names. The present disclosure does not intend to distinguish devices with the same functions but different names. In the following specification and claims, the terminologies “including,” “containing,” “having,” etc. are open-ended terminologies, so they should be interpreted to mean “including but not limited to . . . ”. Therefore, when the terms “including,” “containing,” and/or “having” are used in the description of the present disclosure, the terminologies designate the presence of a corresponding feature, region, step, operation, and/or element, but do not exclude the presence of one or more corresponding features, regions, steps, operations, and/or elements.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

An electrical connection or coupling relationship described in this disclosure may refer to a direct connection or an indirect connection. In the case of the direct connection, end points of the elements on two circuits are directly connected or connected to each other by a conductor segment, In the case of the indirect connection, there are switches, diodes, capacitors, inductors, resistors, other appropriate elements, or a combination of the above elements between the end points of the elements on the two circuits, which should not be construed as a limitation in the disclosure.

Generally, when a signal line on a circuit substrate breaks and causes disconnection (open circuit), a connecting layer can be used to repair the broken signal line and restore its connection, thereby improving the reliability of the electronic device.

The present disclosure provides an electronic device and a method of manufacturing the same to prevent the disconnection of a connecting layer (also known as a repair line). The method of manufacturing the electronic device may, for example, a repair method, capable of repairing defective products or resolving open circuit issues. In accordance with some embodiments of the present disclosure, the insulating layer may be pre-patterned to preserve openings on the signal line. During the repair process, the steps of drilling holes (penetrating to the substrate) and coating to fill the holes can be omitted, allowing for direct coating and wiring. Since the depth of the openings is relatively shallow, the thickness of the coating for the connection layer can be reduced, thereby reducing the processing time. Furthermore, in accordance with some embodiments of the present disclosure, a conductor layer may be disposed in the openings to protect the exposed surface of the signal line, thereby enhancing the reliability of the electronic device.

The electronic device of the present disclosure may include a display device, a backlight device, an antenna device, a sensing device, or a splicing display, but the present disclosure is not limited thereto. The electronic device may be a bendable or flexible electronic device. The display device may be a non-self-emissive display device or a self-emissive display device. The antenna device may be a liquid-crystal antenna or a non-liquid-crystal antenna, and the sensing device may be a sensing device that senses capacitance, light, heat energy or ultrasonic waves, but the present disclosure is not limited thereto. The electronic component may include a passive component and an active component, such as a capacitor, a resistor, an inductor, a diode, a transistor, etc. The diodes may include a light-emitting diode or a photodiode. The light-emitting diode may include, for example, an organic light-emitting diode (OLED), a mini light-emitting diode (mini LED), a micro light-emitting diode (micro LED) or a quantum dot light-emitting diode (QDLED), but the present disclosure is not limited thereto. The splicing device may be, for example, a display splicing device or an antenna splicing device, but the present disclosure is not limited thereto. It should be noted that, the electronic device can be any arrangement and combination of the aforementioned devices, but the present disclosure is not limited thereto. The concepts or principles of the present disclosure are applicable to a non-self-emissive liquid crystal display (LCD) or a thin-film transistor liquid crystal display (TFT LCD), but the present disclosure is not limited thereto. In the following, the electronic device will be described in the context of a display device or a splicing device, but the present disclosure is not limited thereto.

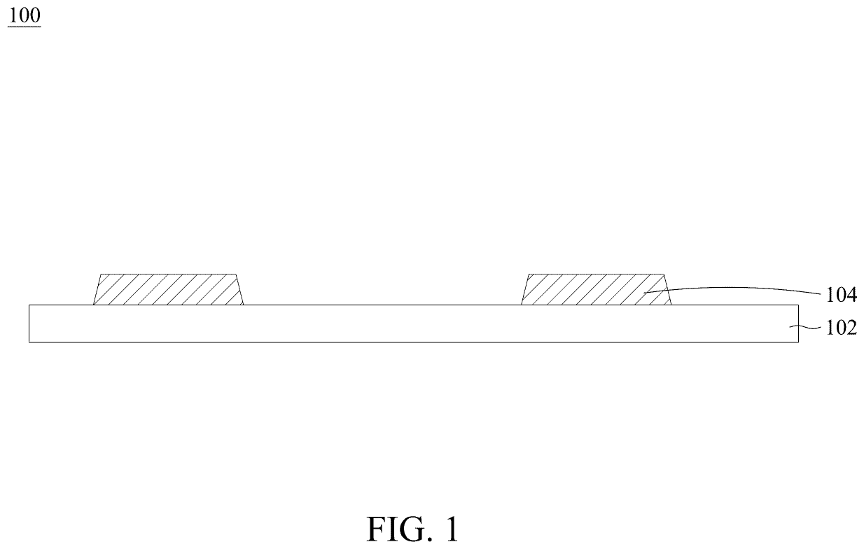

FIGS. 1-6 are cross-sectional views of the intermediate stages of manufacturing an electronic device 100, in accordance with some embodiments. It should be noted that, for clarity of concise explanation, some components of the electronic device 100 may be omitted in the drawings, and only some components are schematically illustrated. In accordance with some embodiments, additional features can be added to the electronic device 100 described below.

Referring to FIG. 1, in one embodiment, a first substrate 102 is provided. In some embodiments, the first substrate 102 may include an array substrate, a polarizer, a thin film transistor (TFT) substrate, a capacitor, an integrated circuit (IC), an indium-tin oxide (ITO) pixel electrode or combinations thereof, but the present disclosure is not limited thereto. The first substrate 102 referred to in this disclosure includes a rigid substrate, a flexible substrate, or combinations thereof. For example, the material of the first substrate 102 may include glass, quartz, sapphire, acrylic resin, polyethylene (PC), polyimide (PI), polyethylene terephthalate (PET), other suitable transparent materials, or combinations thereof, but the present disclosure is not limited thereto.

In one embodiment, a signal line 104 is formed on the substrate 102. In some embodiments, the signal line 104 may include a current signal line, a voltage signal line, a high-frequency signal line, and a low-frequency signal line, and the signal line can transmit the device operating voltage (VDD), the ground terminal voltage (VSS), or the driving element terminal voltage, but the present disclosure is not limited thereto. In some embodiments, the material of the signal line 104 may include copper (Cu), aluminum (Al), indium (In), ruthenium (Ru), tin (Sn), gold (Au), platinum (Pt), molybdenum (Mo), zinc (Zn), silver (Ag), titanium (Ti), lead (Pb), nickel (Ni), neodymium (Nd), iridium (Ir), chromium (Cr), magnesium (Mg), palladium (Pd), lithium (Li), calcium (Ca), an alloy thereof, other suitable metal materials, or combinations thereof, but the present disclosure is not limited thereto.

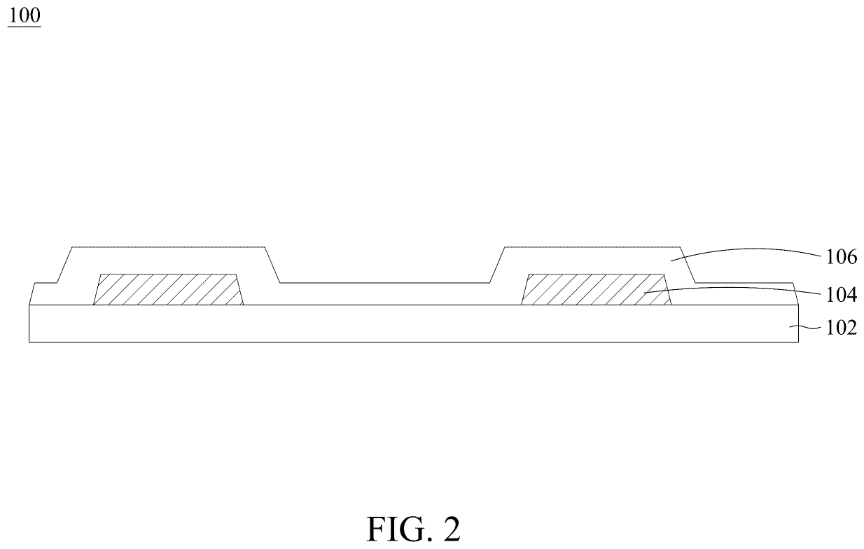

Referring to FIG. 2, in one embodiment, an insulating layer 106 is formed on the signal line 104. In some embodiments, the material of the insulating layer 106 includes an organic material, an inorganic material, combinations thereof, or other suitable materials, but the present disclosure is not limited thereto. In accordance with some embodiments, the organic material may include epoxy resin, silicone resin, acrylic resin (such as polymethylmethacrylate (PMMA)), benzocyclobutene (BCB), polyimide, polyester, polydimethylsiloxane (PDMS), perfluoroalkoxy alkane (PFA), other suitable materials, or combinations thereof, but the present disclosure is not limited thereto. In some embodiments, the insulating layer may be a single-layer structure or a multi-layer structure.

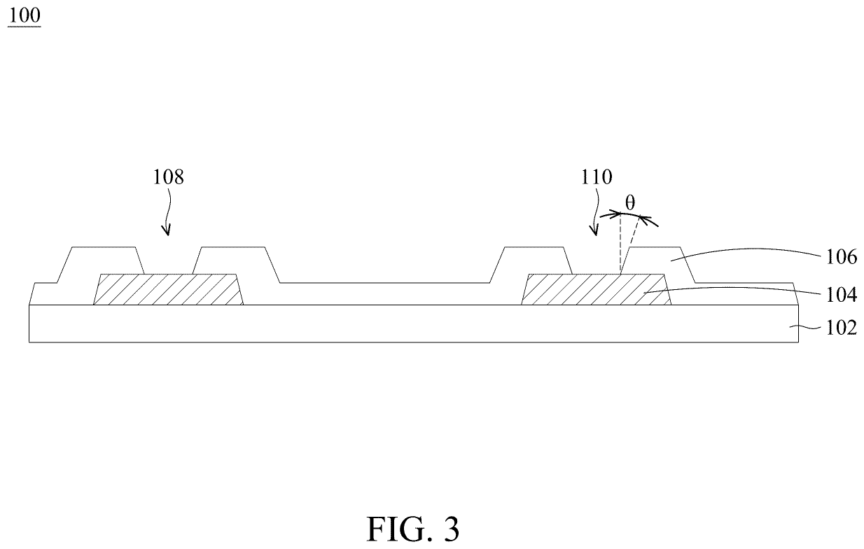

Referring to FIG. 3, in one embodiment, the insulating layer 106 is patterned to form a first opening 108 and a second opening 110, wherein the first opening 108 and the second opening 110 expose the signal line 104. It should be noted that while FIG. 3 illustrates the first opening 108 and the second opening 110 corresponding to respective signal lines 104, but the present disclosure is not limited thereto. In other embodiments, the first opening 108 and the second opening 110 may respectively correspond to common electrodes, scan lines, or data lines, but the present disclosure is not limited thereto. In some embodiments, the first opening 108 and the second opening 110 may have a tapered cross-sectional profile towards the first substrate 102, but the present disclosure is not limited thereto. In some embodiments, the sidewalls of the first opening 108 and second opening 110 may have an inclination angle θ ranging from 30° to 50° (e.g., 35°, 40°, or 45°). The above-mentioned inclination angle θ means that the angle between the sidewall surface of the opening and the normal line of the first substrate 102. An inclination angle θ within the range of 30° to 50° can improve subsequent coating quality.

The patterning process for the first opening 108 and the second opening 110 may include a photolithography process and an etching process. A photomask is used to define a photoresist pattern on the insulating layer 106 to be patterned. Subsequently, the insulating layer 106 is etched using the photoresist pattern as a mask to form the first opening 108 and the second opening 110. In accordance with some embodiments, the photolithography process may include, but is not limited to, photoresist coating (such as spin coating), soft baking, hard baking, mask alignment, exposure, post-exposure baking, photoresist development, cleaning, and drying. The etching process may include, but is not limited to, dry etching process or wet etching process. The etching conditions need to remove the insulating layer 106 above the signal line 104 to expose the signal line 104.

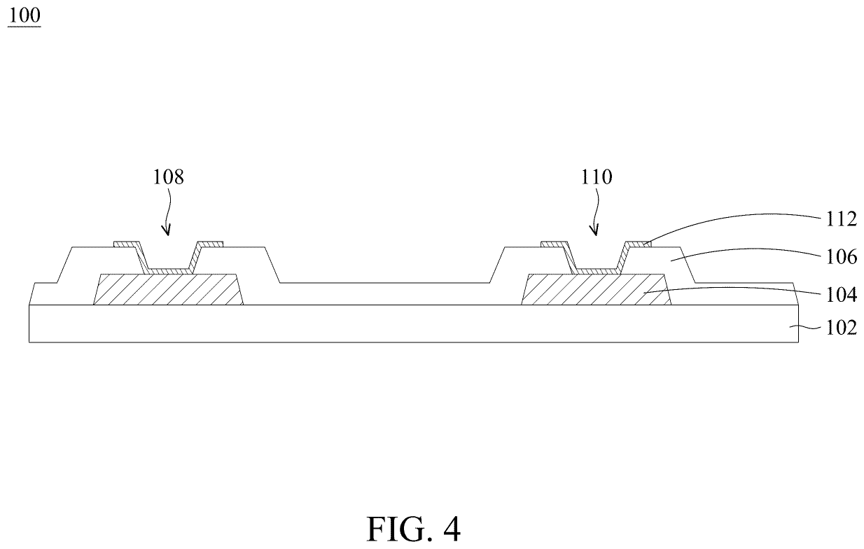

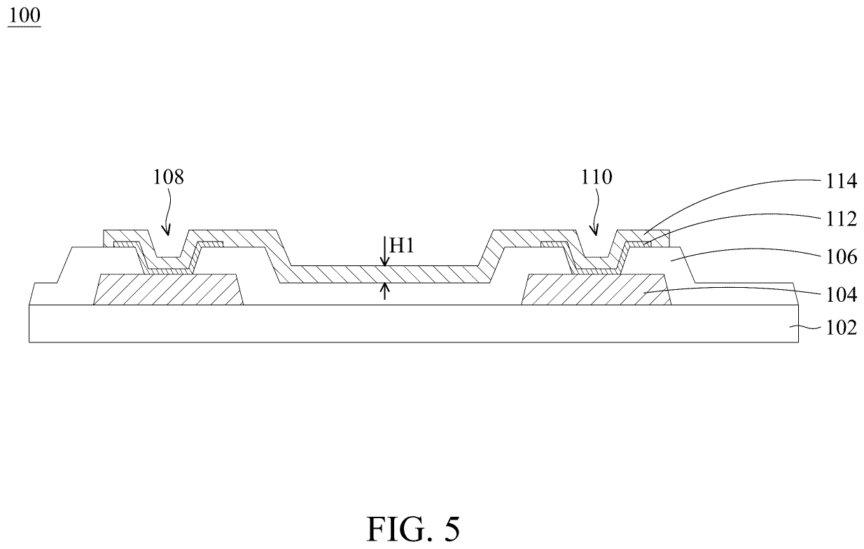

Referring to FIG. 4, in one embodiment, a conductor layer 112 is formed in the first opening 108, the second opening 110, and on the signal line 104. In some embodiments, the conductor layer 112 is conformally formed in the first opening 108 and the second opening 110, covering the exposed surface of the signal line 104. The conductor layer 112 serves to protect the surface of the signal line 104 exposed by the first opening 108 and the second opening 110, to prevent oxidation or corrosion of the signal line 104 during other processes before the repair process, which could otherwise affect the electrical connection between the signal line 104 and the connection layer 114 (as shown in FIG. 5). As depicted, the conductor layer 112 conformally covers the bottom and sidewalls of the first opening 108 and the second opening 110, and extend to the top surface of the insulating layer 106, but the present disclosure is not limited thereto. In other embodiments, the conductor layer 112 may not extend to the top surface of the insulating layer 106 or may not conformally cover in the opening, as long as the conductor layer 112 covers the surface of the signal line 104 to provide protection.

In some embodiments, the conductor layer 112 may include metallic conductive materials (such as copper, aluminum, silver, or gold), transparent conductive materials (such as indium-tin oxide (ITO), indium gallium zinc oxide (IGZO), or aluminum zinc oxide (AZO)), other suitable types of conductive materials, or combinations thereof, but the present disclosure is not limited thereto. In some embodiments, the conductor layer 112 may be a single-layer structure that directly contacts the signal line 104, but the present disclosure is not limited thereto. In some embodiments, the conductor layer 112 may have a thickness ranging from 500 Å to 1200 Å (e.g., 600 Å to 1100 Å, 700 Å to 1000 Å, or 800 Å to 900 Å). The thickness within the range of 500 Å to 1200 Å can enhance reliability.

In some embodiments, a conductive material layer (not shown) may be formed using a deposition process, followed by a photolithography process and an etching process to pattern the conductive material layer and form the conductor layer 112. In some embodiments, the deposition process may include coating methods such as evaporation, sputtering, and ion beam evaporation, but the present disclosure is not limited thereto. The photolithography process may include, but is not limited to, photoresist coating (such as spin coating), soft baking, hard baking, mask alignment, exposure, post-exposure baking, photoresist development, cleaning, and drying. The etching process may include, but is not limited to, dry etching process or wet etching process.

Referring to FIG. 5, in one embodiment, a connection layer 114 extending from the first opening 108 to the second opening 110 is formed, and the connection layer 114 is electrically connected to the signal line 104 through the conductor layer 112. In some embodiments, if the signal line 104 on the first substrate 102 breaks at a certain point and causes an open circuit, the connection layer 114 can be used to electrically connect the two signal lines 104 through the conductor layer 112, thereby restoring connectivity and improving the reliability of electronic devices.

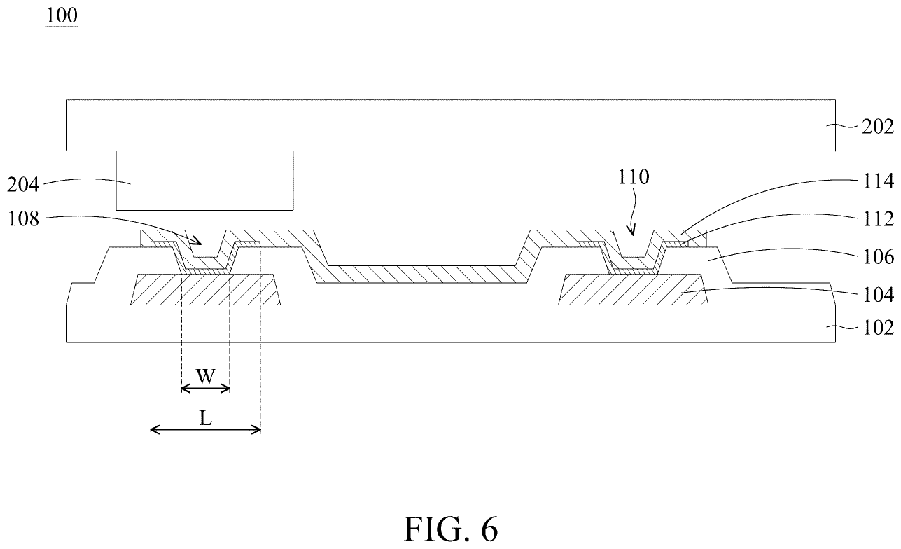

In some embodiments of the present disclosure, it should be noted that the insulating layer 106 may be pre-patterned to preserve the first opening 108 and the second opening 110 on the signal line 104, direct coating and wiring can be performed during the subsequent repair process. Since the depths of the first opening 108 and the second opening 110 are relatively shallow, the thickness of the coating for the connection layer 114 can be reduced, thereby reducing the processing time. In some embodiments, when applied to a display, this approach can prevent issues such as the connection layer 114 being crushed by the spacer 204 (as shown in FIG. 6).

In one embodiment, the thickness H1 of the connection layer 114 ranges from 0.3 to 0.5 μm (e.g., 0.4 μm), which enhances the electrical performance of the connection layer 114. In some embodiments, the connection layer 114 may include metal complex materials such as nickel tetracarbonyl (Ni(CO)₄), iron pentacarbonyl (Fe(CO)₅), chromium hexacarbonyl (Cr(CO)₆), molybdenum hexacarbonyl (Mo(CO)₆), tungsten hexacarbonyl (W(CO)₆), or other suitable materials formed using laser chemical vapor deposition (LCVD) process technology. Alternatively, the connection layer 114 can be composed of conductive glue which typically includes a conductive substance and a matrix material, the conductive substance such as metal powder, carbon black, or conductive polymer, mixed with a matrix material like polymer, rubber, or composite materials, but the present disclosure is not limited thereto. In one embodiment, the connection layer 114 may be a tungsten metal layer (not shown) formed using tungsten hexacarbonyl (W(CO)₆) as a source gas through LCVD process technology. In some embodiments, the metal complex materials may be formed using a photolithography process and an etching process to form the connection layer 114. The photolithography process may include, but is not limited to, photoresist coating (such as spin coating), soft baking, hard baking, mask alignment, exposure, post-exposure baking, photoresist development, cleaning, and drying. The etching process may include, but is not limited to, dry etching process or wet etching process.

As illustrated in FIG. 5, in one embodiment, an electronic device 100 provided by the present disclosure includes a first substrate 102, a signal line 102 disposed on the first substrate 102, an insulating layer 106 disposed on the signal line 104, which comprises a first opening 108 and a second opening 110 that expose the signal line 104, a conductor layer 112 disposed in the first opening 108, the second opening 110, and on the signal line 104, and a connection layer 114. The connection layer 114 extends from the first opening 108 to the second opening 110 and electrically connects the signal line 104 through the conductor layer 112.

Referring to FIG. 6, in one embodiment, the electronic device 100 further includes a second substrate 202 disposed opposite the first substrate 102, and at least one spacer 204 disposed on the second substrate 202 between the first substrate 102 and the second substrate 202. In some embodiments, the spacer 204 is configured to support both the first substrate 102 and the second substrate 202. In this embodiment, the first substrate 102 may include a thin film transistor substrate, while the second substrate 202 may include a color filter array substrate (COA). The spacer 204 is configured to ensure sufficient gap height and uniformity between the first substrate 102 and the second substrate 202, creating space to accommodate the liquid crystal (not shown) between the first substrate 102 and the second substrate 202, but the present disclosure is not limited thereto. In other embodiments, the spacer 204 is configured to support the second substrate 202 to prevent the second substrate 202 from warping.

In some embodiments, the material of the spacer 204 may include photoresist (i.e., photo spacer), polymer (i.e., polymer pattern), metal (i.e., metal pattern), film, tape, glue or underfill, but the present disclosure is not limited thereto. In some embodiments, the shape of the spacer 204 may include spherical, columnar, trapezoidal, inverted trapezoidal, etc., but the present disclosure is not limited thereto. In some embodiments, the spacers 204 may be distributed regularly or irregularly throughout the electronic device 100. It should be noted that although FIG. 6 illustrates only one columnar spacer 204, the present disclosure is not limited thereto. In other embodiments, various sizes, arrangements, and numbers of the spacers 204 can be configured in the electronic device 100.

In one embodiment, at least one spacer 204 overlaps with the first opening 108, that is, the spacer 204 may overlap with the first opening 108 or the second opening 110, or there may be two spacers 204 overlapping the first opening 108 and the second opening 110, respectively.

By the manufacturing method of the electronic device 100 provided in the present disclosure, direct coating and wiring can be performed during the repair process. In some embodiments, when applied to a display, this approach can prevent the connection layer 114 from being crushed by the spacer 204, thereby enhancing product yield and reliability.

In one embodiment, in a cross-sectional view, the first opening 108 has a first width W in the direction that is perpendicular to the normal direction of the first substrate 102. In some embodiments, the first width W may refer to the width of the opening on the lower surface of the insulating layer 106 or the width of the signal line 104 exposed by the first opening 108. The conductor layer 112 has a first length L in the direction that is perpendicular to the normal direction of the first substrate 102. The above-mentioned first width W and first length L in a cross-sectional view can be measured, for example, using an optical microscope (OM) or a scanning electron microscope (SEM). Specifically, the first width W represents the surface width of the signal line 104 exposed by the first opening 108 or the second opening 110, while the first length L is the maximum length of the conductor layer 112 in the cross-sectional view. In one embodiment, the ratio of the first length L to the first width W is greater than or equal to 1.5 and less than or equal to 2 (2≥L/W≥1.5) to ensure that the conductor layer 112 fully covers the surface of the signal line 104 exposed by the first opening 108 or the second opening 110, thereby enhancing the reliability of the electronic device 100.

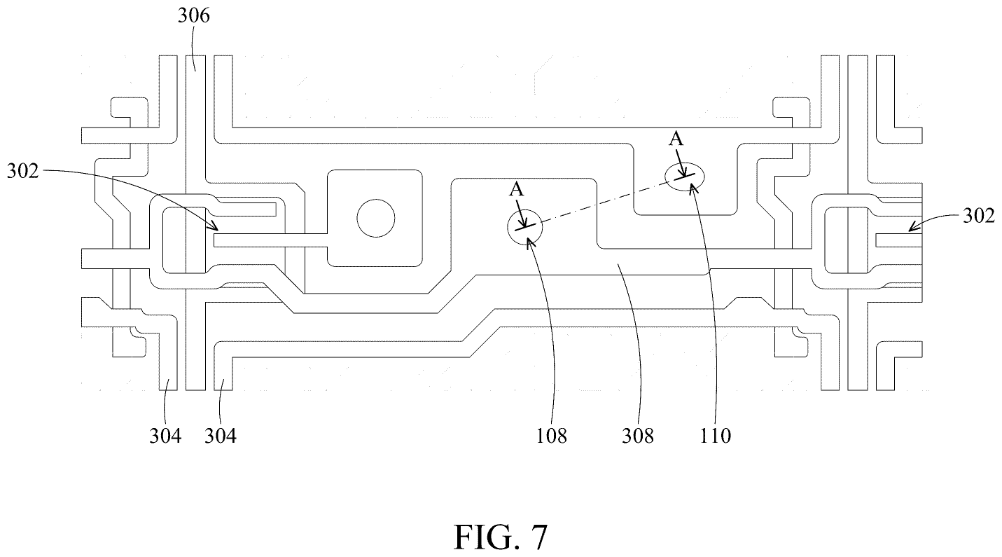

FIG. 7 is a top view of the intermediate stages of manufacturing an electronic device 100, in accordance with one embodiment of the present disclosure. The preceding FIGS. 1-6 are illustrated along line A-A in FIG. 7.

Referring to FIG. 7, in some embodiments, the electronic device 100 further includes a driving structure 302, a common electrode 304, a scan line 306, and a data line 308, but the present disclosure is not limited thereto. In some embodiments, the driving structure 302 may include active components, passive components, or a combination thereof, but the present disclosure is not limited thereto. In this embodiment, the driving structure 302 may include a thin film transistor (TFT). In some embodiments, the thin film transistor may include a switching transistor, a driving transistor, a reset transistor, a transistor amplifier, or other suitable types of thin film transistors, but the present disclosure is not limited thereto.

In one embodiment, in a top view, the first opening 108 is disposed immediately adjacent to the second opening 110. The term “immediately adjacent” as used herein refers to the two closest openings, with no other openings present between them. In one embodiment, in a top view, the first opening 108 and the second opening 110 are disposed between adjacent driving structures 302.

It should be understood that after assembling the first substrate 102 and the second substrate 202, subsequent processes can be carried out as needed to complete the production of the electronic device 100. Since these processes are not directly related to the focus of this disclosure, for brevity they are not described herein.

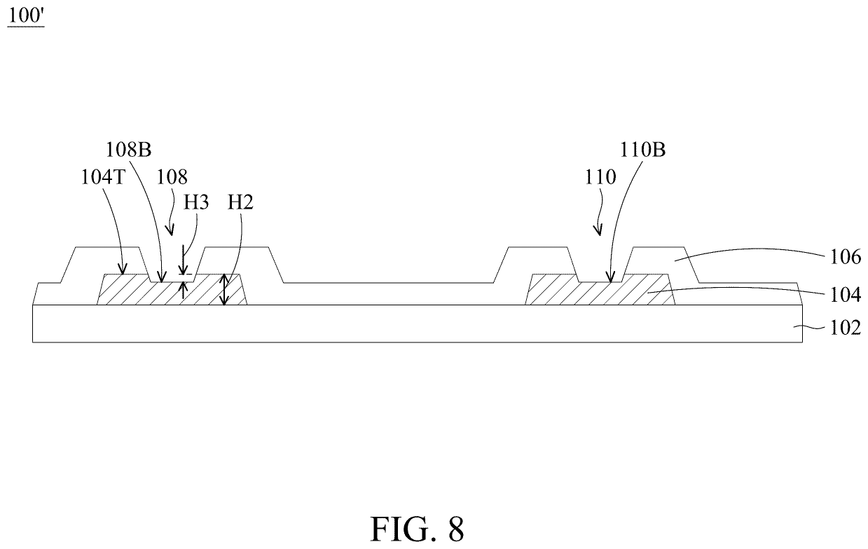

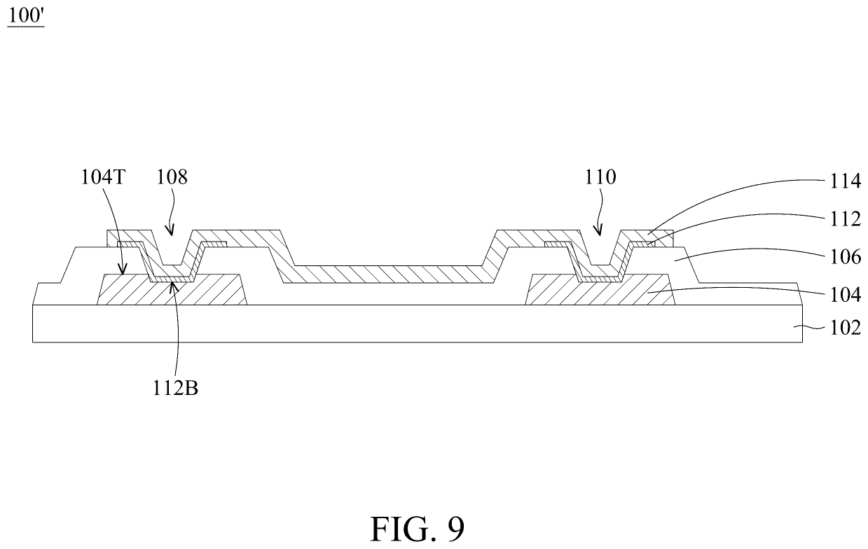

Other embodiments of the present disclosure will be described below with reference to FIGS. 8-9. FIGS. 8-9 are cross-sectional views of the intermediate stages of manufacturing an electronic device 100′, in accordance with other embodiments. It should be noted that the features between the various embodiments can be combined and used interchangeably as long as they do not violate or conflict with the spirit of the disclosure.

In other embodiments, FIG. 8 follows the steps depicted in FIG. 2. The electronic device 100′ in FIG. 8 is similar to the electronic device 100 in FIG. 3, except that both the bottom surface 108B of the first opening 108 and the bottom surface 110B of the second opening 110 are lower than the top surface 104T of the signal line 104. Specifically, in this embodiment, over-etching is performed during the process of patterning the insulating layer 106 to form the first openings 108 and the second openings 110, ensuring complete removal of the insulation layer in the first opening 108 and the second opening 110. Therefore, a portion of the signal line 104 may be recessed during the over-etching process, resulting in a concave top surface. Specifically, the signal line 104 may have a height H2 in the normal direction of the first substrate 102, and its concave top surface may have a depth H3. The height H2 and the depth H3 may satisfy the following equation: 20%≥H3/H2≥5%, ensuring better reliability of the electronic device.

Referring to FIG. 9, in some embodiments, the conductor layer 112 and the connection layer 114 are formed after over-etching the signal line 104. The connection layer 114 is formed not only in the first opening 108 and the second opening 110 but also on the exposed surface of the signal line 104 after over-etching. As depicted, the conductor layer 112 conformally covers the bottom (the exposed surface of the signal line 104 after over-etching) and the sidewalls of both the first opening 108 and the second opening 110, and extends to the top surface of the insulating layer 106, but the present disclosure is not limited thereto. In some embodiments, after forming the conductor layer 112, a connection layer 114 extending from the first opening 108 to the second opening 110 is formed, and the connection layer 114 electrically connects the signal line 104 through the conductor layer 112. In one embodiment, the bottom surface 112B of the conductor layer 112 is at a lower level than the top surface 104T of the signal line 104. Other process details are the same as those discussed above, and for brevity they are not repeated herein.

In summary, the present disclosure provides an electronic device and a method of manufacturing the same to prevent the disconnection of a connecting layer (also known as a repair line). In accordance with some embodiments of the present disclosure, the insulating layer may be pre-patterned to preserve openings on the signal line, direct coating and wiring can be performed during the repair process. Since the depth of the openings is relatively shallow, the thickness of the coating for the connection layer can be reduced, thereby reducing the processing time. Furthermore, in accordance with some embodiments of the present disclosure, a conductor layer may be disposed in the openings to protect the exposed surface of the signal line, thereby enhancing the reliability of the electronic device. This approach can prevent oxidation or corrosion of the signal line during other processes before the repair process, which could otherwise affect the electrical connection between the signal line and the connection layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An electronic device, comprising:
a first substrate;
a signal line disposed on the first substrate;
an insulating layer disposed on the signal line, wherein the insulating layer comprises a first opening and a second opening that expose the signal line;
a conductor layer disposed in the first opening and the second opening and on the signal line; and
a connection layer extending from the first opening to the second opening and electrically connected to the signal line through the conductor layer.

2. The electronic device of claim 1, wherein each of the first opening and the second opening has a tapered profile that tapers toward the first substrate.

3. The electronic device of claim 2, wherein sidewalls of the first opening and the second opening have an inclination angle in a range of 30° to 50° relative to a normal direction of the first substrate.

4. The electronic device of claim 1, wherein the conductor layer is indium tin oxide.

5. The electronic device of claim 1, wherein the conductor layer is further disposed on a top surface of the insulating layer.

6. The electronic device of claim 1, wherein the conductor layer conformally covers bottoms and sidewalls of the first opening and the second opening.

7. The electronic device of claim 6, wherein the conductor layer has a thickness in a range of 500 Å to 1200 Å.

8. The electronic device of claim 1, wherein the connection layer has a thickness in a range of 0.3 to 0.5 μm.

9. The electronic device of claim 1, further comprising:
a second substrate disposed opposite to the first substrate; and
at least one spacer disposed on the second substrate and between the first substrate and the second substrate.

10. The electronic device of claim 9, wherein the first substrate is a thin film transistor substrate, and the second substrate is a color filter array substrate.

11. The electronic device of claim 9, wherein the at least one spacer overlaps the first opening.

12. The electronic device of claim 1, wherein in a cross-sectional view, the first opening has a first width in a direction perpendicular to a normal direction of the first substrate, and the conductor layer has a first length in the direction perpendicular the normal direction of the first substrate, and a ratio of the first length to the first width is greater than or equal to 1.5 and less than or equal to 2.

13. The electronic device of claim 1, wherein in a top view, the first opening is disposed immediately adjacent to the second opening.

14. The electronic device of claim 1, wherein in a top view, the first opening and the second opening are disposed between adjacent driving structures.

15. The electronic device of claim 1, wherein a bottom surface of the conductor layer is at a level lower than a top surface of the signal line.

16. The electronic device of claim 15, wherein in a cross-sectional view, the signal line has an upper surface recessed to a depth in a normal direction of the first substrate, and a ratio of the depth to a height of the signal line is greater than or equal to 5% and less than or equal to 20%.

17. A method of manufacturing an electronic device, comprising:
providing a first substrate;
forming a signal line on the first substrate;
forming an insulating layer on the signal line;
patterning the insulating layer to form a first opening and a second opening, wherein the first opening and the second opening expose the signal line;
forming a conductor layer in the first opening and the second opening and on the signal line; and
forming a connection layer extending from the first opening to the second opening, wherein the connection layer is electrically connected to the signal line through the conductor layer.

18. The method of claim 17, wherein the connection layer is a tungsten metal layer formed by laser chemical vapor deposition using W(CO)₆ as a source gas.

19. The method of claim 17, wherein the step of patterning the insulating layer further comprises recessing a portion of the signal line.

20. The method of claim 19, wherein the step of forming the connection layer further comprises forming the connection layer on a recessed surface of the signal line.
